(19) United States
(12) Patent Application Publication
(10) Pub. No.: US 2008/0150146 A1
(43) Pub. Date: Jun. 26, 2008

(54) SEMICONDUCTOR DEVICE AND METHOD OF FABRICATING THE SAME

(76) Inventor: Yong-Suk Lee, Seoul (KR)

Correspondence Address: SHERR & NOURSE, PLLC, 620 HERNDON PARKWAY, SUITE 200, HERNDON, VA, 20170, US

(21) Appl. No.: 11/957,152

(22) Filed: Dec. 14, 2007

(30) Foreign Application Priority Data
Dec. 22, 2006 (KR) 10-2006-0132689

(51) Int. Cl. H01L 23/48; H01L 21/768

(52) U.S. Cl. 257/763; 438/656; 257/E21.575; 257/E23.01

(57) ABSTRACT

A semiconductor device such as a CMOS image sensor and a method of fabricating the same, in which a stable alignment mark is formed. The semiconductor device includes an isolation layer formed in a scribe lane region of a semiconductor substrate and having a groove, an insulating layer having a hole through which the groove is exposed and formed on the semiconductor substrate, and a metal layer formed on the groove and the hole. The groove is formed in the isolation layer and is used as an alignment mark formation region. Thus, although the thickness of an interlayer insulating layer is not thick, it can be compensated for by the groove formed in the isolation layer.

The present application claims priority under 35 U.S.C. 119 to Korean Patent Application No. 10-2006-0132689, filed on Dec. 22, 2006, which is hereby incorporated by reference in its entirety.

### BACKGROUND

Development of semiconductor devices have focused on producing a pure silicon wafer from silicon, forming a plurality of semiconductor chips in which endless ultra-micro thin film circuits are integrated on the wafer, singulating the semiconductor chips, and then packaging and testing the chips. Semiconductor devices fabricated through this process can process vast amounts of data within a short period of time and can have vast amounts of data integrated in a unit area, and thus, have been widely applied and used in a variety of sectors.

To obtain such advantages, a process of forming an ultra-micro thin film circuit on and/or over a semiconductor chip may be performed through semiconductor fabrication processes such as deposition, etching, and ion implantation of a plurality of thin films having intrinsic properties.

In order for the plurality of thin films to constitute a circuit, previous thin films and subsequent thin films have to be aligned. Such alignment may be accomplished using an “alignment key” or “alignment mark” formed in a scribe line, etc., which exists between the semiconductor chips.

The alignment mark can be implemented by depositing thin film material in a groove formed for an alignment mark or can be implemented in a groove form by etching a thin film.

Defective alignment marks may occur, however, in the fabrication process of semiconductor devices such as a CMOS image sensor.

An image sensor is a semiconductor device for converting an optical image into an electrical signal and may be classified into a charge-coupled device (CCD) and a CMOS image sensor.

The CMOS image sensor may have a plurality of MOS transistors which correspond to a unit pixel formed in a semiconductor substrate. The MOS transistors may be formed by employing a CMOS technique using a control circuit, a signal processing circuit, etc. as peripheral circuits, and adopts a switching method of sequentially detecting the output of each unit pixel by using the MOS transistors.

There is a tendency that in the CMOS image sensor, the thickness of an interlayer insulating layer may gradually decrease so as to improve light transmission. This results in several problems when an alignment mark is formed in an interlayer insulating layer having a shallow thickness.

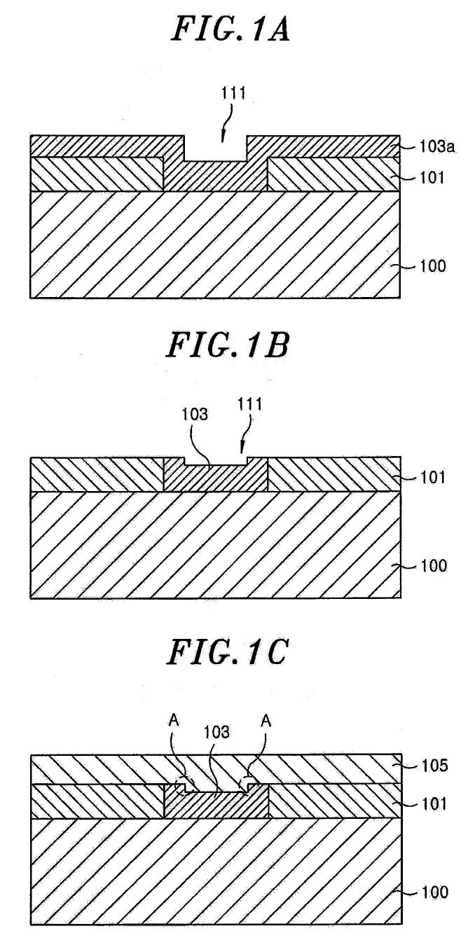

As illustrated in example FIG. 1A, a CMOS image sensor may include interlayer insulating layer 101 formed on and/or over semiconductor substrate 100. Interlayer insulating layer 101 may have a thickness of between 3000 to 10,000 Å. Interlayer insulating layer 101 may also be formed to a thickness of between 4000 to 5000 Å. Hole 111 in which an alignment mark will be formed may be formed in interlayer insulating layer 101.

Metal layer 103a composed of tungsten may be deposited on and/or over interlayer insulating layer 101 including hole 111. In order to planarize the uppermost surface, tungsten layer 103a may be polished by a chemical mechanical polishing (CMP) method which also exposes the uppermost surface of interlayer insulating layer 101 and leaves only tungsten layer 103 in hole 111.

As illustrated in example FIG. 1B, step “A” may be rarely generated in tungsten layer 103 because the thickness of interlayer insulating layer 101 is thin and the depth of the hole 111 is shallow.

As illustrated in example FIG. 1C, metal layer 105 composed of aluminum (Al) may be formed on and/or over interlayer insulating layer 101 including tungsten layer 103. In this case, step “A” may be rarely generated in tungsten layer 103, resulting in a flat alignment mark.

The alignment mark serves as an alignment mark because a signal is generated from step “A” portion. The flat alignment mark not only has almost no step, but also does not allow the aluminum layer 105, stacked on and/or over tungsten layer 103, to transmit light. Thus, the flat alignment mark does not serve as an alignment mark. Accordingly, there is a problem in that pattern failure occurs since alignment is not properly performed at the time of a photolithography process of the aluminum layer.

### SUMMARY

Embodiments relate to a method of fabricating a semiconductor device in which a stable alignment mark can be formed.

Embodiments relate to a semiconductor device and a method of fabricating the same, in which a stable alignment mark is constructed of an alignment mark having a sufficient step, thus improving process reliability.

Embodiments relate to a semiconductor device that may include an isolation layer formed in a scribe lane region of a semiconductor substrate, the isolation layer having an alignment mark region defined therein; a metal layer formed over the semiconductor substrate and the isolation layer; an alignment mark formation hole including a groove formed in the isolation layer and a hole formed in the metal layer, wherein the hole corresponds to the groove and through which the groove is exposed; and an insulating layer formed over the metal layer and filled into the groove and the hole.

Embodiments relate to a semiconductor device including an isolation layer formed in a scribe lane region of a semiconductor substrate, wherein the isolation layer includes a groove; an insulating layer formed over the semiconductor substrate including the isolation layer, the insulating layer having a hole corresponding to the groove and through which the groove is exposed; and a metal layer formed in the groove and the hole.

Embodiments relate to a method of fabricating a semiconductor device, including at least one of the following steps: forming an isolation layer in a scribe lane region of a semiconductor substrate; forming an insulating layer over the isolation layer; forming a hole in the insulating layer through which a portion of the isolation layer is exposed; forming a groove in the isolation layer; forming a metal layer over the insulating layer and in the hole and the groove; and then removing a portion of the metal layer over the insulating layer.

### DRAWINGS

Example FIGS. 1A to 1C illustrate a process of forming an alignment mark in a CMOS image sensor.

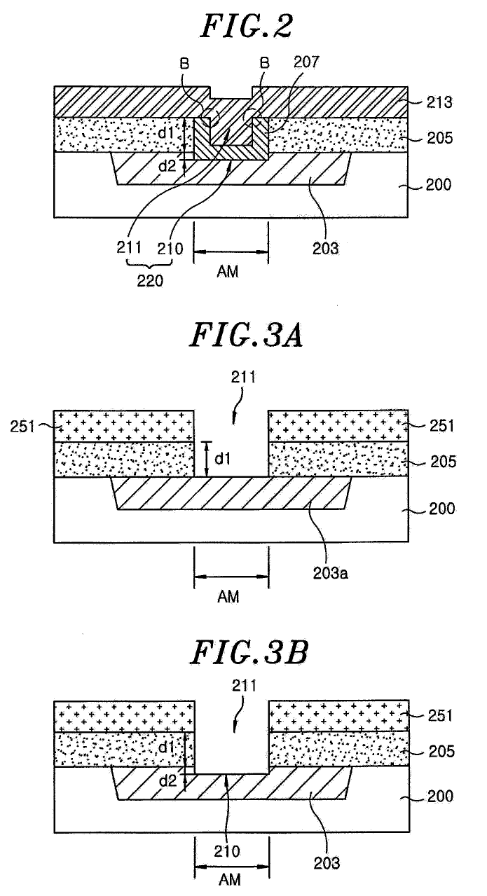

Example FIG. 2 illustrates an alignment mark of a semiconductor device, in accordance with embodiments.

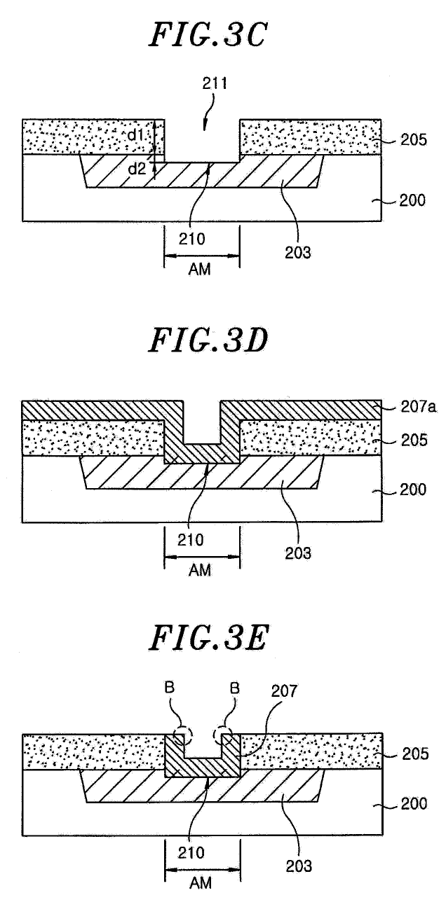

Example FIG. 3A to 3F illustrates a method of forming an alignment mark of a semiconductor device, in accordance with embodiments.

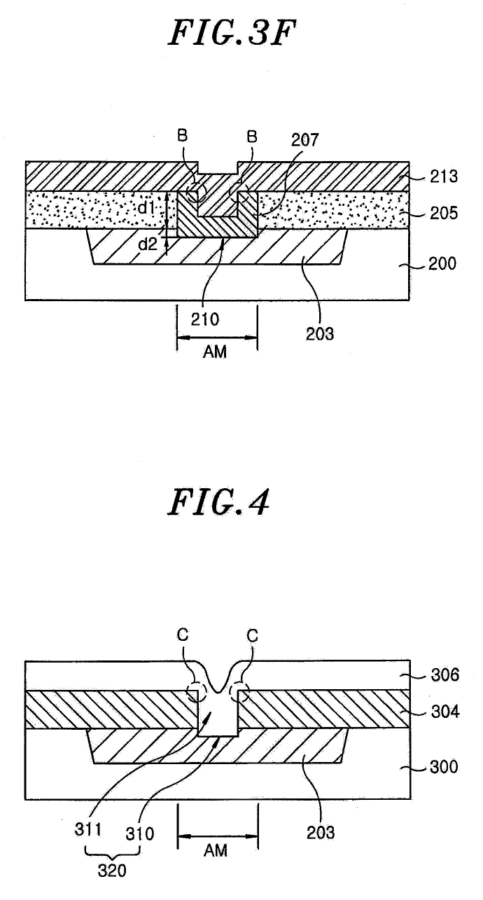

Example FIG. 4 illustrates an alignment mark of a semiconductor device, in accordance with embodiments.

### DESCRIPTION

As illustrated in example FIG. 2, a semiconductor device in accordance with embodiments can include isolation layer 203 formed in a scribe lane region of semiconductor substrate 200. Alignment mark region AM can be defined in isolation layer 203. Isolation layer 203 can be formed so that an alignment mark has a sufficient step “B” in forming alignment mark region AM. Isolation layer 203 can include groove 210 in alignment mark region AM. The depth of groove 210 can range from between 1000 to 4000 Å.

Interlayer insulating layer 205 can be formed on and/or over semiconductor substrate 200 including isolation layer 203. The thickness of interlayer insulating layer 205 can range from between 3000 to 10,000 Å. Interlayer insulating layer 205 may preferably have a thickness of between 4000 to 5000 Å.

Interlayer insulating layer 205 can include hole 211 corresponding to groove 210 and through which groove 210 is exposed. Groove 210 can be formed by an over-etch process during formation of hole 211 in order that the size (i.e., width) of hole 211 can be substantially equal to that of groove 210. The depth of hole 211 formed in interlayer insulating layer 205 can range from between 3000 to 10,000 Å, and preferably, 4000 to 5000 Å. Consequently, the depth of alignment mark formation hole 220 which includes groove 210 and hole 211 can range from between 5500 to 6500 Å.

First metal layer 207 can be formed on and/or over interlayer insulating layer 205 and isolation layer 203 in which alignment mark formation hole 220 is formed. First metal layer 207 can be composed of tungsten and formed in alignment mark formation hole 220, i.e., on and/or over the internal walls and bottom area of alignment mark formation hole 220. Since the depth of alignment mark formation hole 220 is sufficiently deep, first metal layer 207 can have a stepped structure.

Second metal layer 213 can be formed on and/or over first metal layer 207 and interlayer insulating layer 205. Second metal layer 213 can be composed of aluminum and be stepped by the step of first metal layer 207 formed in alignment mark formation hole 220. If step B of the alignment mark is sufficiently great, a high signal can be generated from step B, so that a photomask can be easily aligned at the time of a photolithographic process. Therefore, when second metal layer 213 is patterned subsequently, an optical focus can be positioned correctly in the photolithographic process. Thus, a good pattern can be formed.

Accordingly, in the semiconductor device in accordance with embodiments, groove 210 can be formed in isolation layer 203 of the scribe lane region and can be used as alignment mark region AM. Thus, although the thickness of interlayer insulating layer 205 is not sufficiently thick, it can be compensated for by groove 210 formed in isolation layer 203. It is therefore possible to form a stable alignment mark in the CMOS image sensor.

In the CMOS image sensor, there can be a tendency that the thickness of interlayer insulating layer 205 gradually decreases in order to improve light transmission. In accordance with embodiments, since the thickness of interlayer insulating layer 205 can be formed thin, the optical characteristic of the CMOS image sensor can be improved and strong product competitiveness can be secured.

As illustrated in example FIG. 3A, a process of forming an alignment mark in a semiconductor device in accordance with embodiments may include forming isolation layer 203a in the scribe lane region of semiconductor substrate 200. Interlayer insulating layer 205 can then be formed on and/or over the entire surface of semiconductor substrate 200 including isolation layer 203. The thickness of interlayer insulating layer 205 can range from between 3000 to 10,000 Å, and preferably 4000 to 5000 Å.

Photoresist pattern 251 can then be formed on and/or over interlayer insulating layer 205. Hole 211 may be formed in interlayer insulating layer 205 by etching interlayer insulating layer 205 using photoresist pattern 251 as an etch mask, thus exposing a portion of the uppermost surface of isolation layer 203. The depth of hole 211 can range from between 3000 to 10,000 Å, and preferably 4000 to 5000 Å.

As illustrated in example FIG. 3B, the exposed uppermost surface of isolation layer 203 can then be etched using photoresist pattern 251 as an etch mask, thus forming groove 210 in isolation layer 203. Groove 210 can be formed by an over-etch process when forming hole 211. The depth of groove 210 can range from between 1000 to 4000 Å. Accordingly, alignment mark formation hole 220 is formed and includes groove 210 and hole 211. The depth of alignment mark formation hole 220 can range from between 5000 to 9000 Å.

As illustrated in example FIG. 3C, photoresist pattern 251 can then be removed, thereby exposing the uppermost surface of interlayer insulating layer 205. Because groove 210 can be formed by over-etching when forming hole 211, the size (i.e., width) of hole 211 can be substantially equal to that of groove 210.

As illustrated in example FIG. 3D, first metal layer 207a composed of tungsten can then be formed on and/or over the entire surface of semiconductor substrate 200 including interlayer insulating layer 205, hole 211, and groove 210. First metal layer 207a can have a thickness of between 1000 to 5000 Å. Step B is constituted by the depths of hole 211 and groove 210.

As illustrated in example in FIG. 3E, a portion of first metal layer 207a provided on and/or over interlayer insulating layer 205 can be removed by a CMP method and can be polished accordingly, thus leaving first metal layer 207 which is formed on the top surface of hole 211 and groove 210.

As illustrated in example FIG. 3F, second metal layer 213 can then be formed over the entire surface of semiconductor substrate 200. Second metal layer 213 can be formed on and/or over the step of first metal layer 207 formed within alignment mark formation hole 220, and therefore, can secure a predetermined step in response to groove 210. Consequently, although light does not transmit well through second metal layer 213, step B can serve well as an alignment mark.

As illustrated in example FIG. 4, in accordance with embodiments, isolation layer 303 can be formed in a scribe lane region of semiconductor device 300. Alignment mark region AM can be defined in isolation layer 303. Isolation layer 303 can have groove 310 in alignment mark region AM. Metal layer 304 can be formed on and/or over the entire surface of semiconductor substrate 300. Metal layer 304 can have hole 311 through which groove 310 is exposed. Groove 310 can be formed by over-etching when forming hole 311, so that hole 311 can have substantially the same size (i.e., width) as that of groove 310. Groove 310 and hole 311 constitute alignment mark formation hole 320.

Insulating layer 306 can then be formed on and/or over metal layer 304 and isolation layer 303 in which alignment mark formation hole 320 is formed. Insulating layer 306 can be filled in alignment mark formation hole 320. If step C of alignment mark formation hole 320 is large, a high signal can be generated from step C, so that a photomask can be easily aligned at the time of performing a photolithographic process. Thus, when a contact hole, etc. is subsequently formed by patterning the insulating layer, an optical focus can be positioned correctly in the photolithographic process. Thus, a good pattern can be formed.

As described above, in the semiconductor device in accordance with embodiments, a groove can be formed in an isolation layer and can be used as an alignment mark formation region. Thus, although the thickness of the interlayer insulating layer is not sufficiently thick, it can be compensated for by the groove formed in the isolation layer. It is therefore possible to form a stable alignment mark in a CMOS image sensor. Accordingly, there is an advantage in that a stable alignment mark can be formed in a CMOS image sensor.

Further, according to the present invention, the thickness of an interlayer insulating layer can be made thinner. Accordingly, there is an advantage in that the optical characteristic of a CMOS image sensor can be improved and strong product competitiveness can be obtained.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
an isolation layer formed in a scribe lane region of a semiconductor substrate, wherein the isolation layer includes a groove;
an insulating layer formed over the semiconductor substrate including the isolation layer, the insulating layer having a hole corresponding to the groove and through which the groove is exposed; and
a metal layer formed in the groove and the hole.

2. The apparatus of claim 1, wherein the metal layer includes a step and surrounds sidewalls and a bottom within the groove and the hole.

3. The apparatus of claim 1, wherein the metal layer comprises a tungsten layer.

4. The apparatus of claim 1, wherein the insulating layer has a thickness of between 3000 to 10,000 Å.

5. The apparatus of claim 1, wherein the insulating layer has a thickness of between 4000 to 5000 Å.

6. The apparatus of claim 1, wherein the hole has a depth of between 1000 to 4000 Å.

7. The apparatus of claim 1, wherein the hole has a depth of between 3000 to 10,000 Å.

8. The apparatus of claim 1, wherein the depth of the hole is between 4000 to 5000 Å.

9. The apparatus of claim 1, further comprising a second metal layer formed over the metal layer.

10. A method comprising:
forming an isolation layer in a scribe lane region of a semiconductor substrate;
forming an insulating layer over the isolation layer;
forming a hole in the insulating layer through which a portion of the isolation layer is exposed;
forming a groove in the isolation layer;
forming a metal layer over the insulating layer and in the hole and the groove; and then
removing a portion of the metal layer over the insulating layer.

11. The method of claim 10, wherein removing a portion of the metal layer over the insulating layer is performed by a chemical mechanical polishing process.

12. The method of claim 10, wherein the insulating layer has a thickness of between 3000 to 10,000 Å.

13. The method of claim 10, wherein the insulating layer has a thickness of between 4000 to 5000 Å.

14. The method of claim 10, wherein forming the groove comprises performing an etching process on the isolation layer exposed through the hole.

15. The method of claim 10, wherein forming the groove comprises performing an over-etching process when forming the hole.

16. The method of claim 10, wherein the depth of the hole is between 3000 to 10,000 Å.

17. The method of claim 10, wherein the depth of the hole is between 4000 to 5000 Å.

18. The method of claim 10, further comprising forming a second metal layer over the metal layer.

19. An apparatus comprising:
an isolation layer formed in a scribe lane region of a semiconductor substrate, the isolation layer having an alignment mark region defined therein;
a metal layer formed over the semiconductor substrate and the isolation layer;
an alignment mark formation hole including a groove formed in the isolation layer and a hole formed in the metal layer, wherein the hole corresponds to the groove and through which the groove is exposed;
an insulating layer formed over the metal layer and filled into the groove and the hole.

20. The apparatus of claim 19, wherein the groove has substantially the same width of the hole.
